(19) United States
(12) Patent Application Publication
(10) Pub. No.: US 2024/0397632 A1
(43) Pub. Date: Nov. 28, 2024

(54) STRETCHABLE DEVICE

(71) Applicant: Murata Manufacturing Co., Ltd., Nagaokakyo-shi (JP)

(72) Inventors: Toshifumi ASUKAI, Nagaokakyo-shi (JP); Hayato KATSU, Nagaokakyo-shi (JP); Kentaro USUI, Nagaokakyo-shi (JP); Fumiko MORI, Nagaokakyo-shi (JP)

(21) Appl. No.: 18/797,598

(22) Filed: Aug. 8, 2024

Related U.S. Application Data
(63) Continuation of application No. PCT/JP2023/005258, filed on Feb. 15, 2023.

(30) Foreign Application Priority Data
Feb. 16, 2022 (JP) 2022-021939

(51) Int. Cl. H05K 3/28; B32B 7/025; H05K 1/02

(52) U.S. Cl. CPC H05K 3/28; B32B 7/025; H05K 1/028

(57) ABSTRACT

A stretchable device including: a stretchable substrate having a first principal surface and a second principal surface; a stretchable wiring on the first principal surface and containing a resin; and a first cover layer covering at least a part of the stretchable wiring, in which a total organic carbon concentration in an extraction liquid when the stretchable device is immersed in ultrapure water for 24 hours is 15 mg/L or less.

### CROSS REFERENCE TO RELATED APPLICATIONS

The present application is a continuation of International application No. PCT/JP2023/005258, filed Feb. 15, 2023, which claims priority to Japanese Patent Application No. 2022-021939, filed Feb. 16, 2022, the entire contents of each of which are incorporated herein by reference.

### TECHNICAL FIELD

The present disclosure relates to a stretchable device.

### BACKGROUND ART

Conventionally, a stretchable device in which a stretchable wiring is mounted on a stretchable substrate and used by being worn on a human body is widely known.

Patent Document 1 discloses that a stretchable substrate (corresponding to a stretchable device) includes a substrate having stretchability, a primer layer provided on the substrate, a conductor portion (corresponding to a stretchable wiring) provided on the primer layer, and an overcoat layer covering the conductor portion.

Patent Document 1: Japanese Patent Application Laid-Open No. 2019-75490

### SUMMARY OF THE DISCLOSURE

Here, in the structure described in Patent Document 1, biological safety is not considered, and biocompatibility may be deteriorated. With such a decrease in biocompatibility, inflammation such as rash may occur when the stretchable device is worn on a human body.

Therefore, an object of the present disclosure is to provide a stretchable device capable of improving biocompatibility.

In order to achieve the above object, in one aspect of the present disclosure, provided is a stretchable device including: a stretchable substrate having a first principal surface and a second principal surface; a stretchable wiring on the first principal surface and containing a resin; and a first cover layer covering at least a part of the stretchable wiring, in which a total organic carbon concentration in an extraction liquid when the stretchable device is immersed in ultrapure water for 24 hours is 15 mg/L or less.

According to the stretchable device according to one aspect of the present disclosure, biocompatibility can be improved.

### BRIEF EXPLANATION OF THE DRAWINGS

FIG. 1A is a perspective view schematically illustrating a stretchable device according to a first embodiment of the present disclosure.

FIG. 1B is a sectional view taken along line IB-IB of FIG. 1A.

FIG. 1C is a top view of FIG. 1A.

FIG. 2A is a perspective view schematically illustrating a stretchable device according to a second embodiment of the present disclosure.

FIG. 2B is a sectional view taken along line IIB-IIB of FIG. 2A.

FIG. 2C is a top view of FIG. 2A.

FIG. 3A is a sectional view of a stretchable device according to a first variation of the second embodiment of the present disclosure.

FIG. 3B is a sectional view of the stretchable device according to the first variation of the second embodiment of the present disclosure.

FIG. 4A is a sectional view of a stretchable device according to a second variation of the second embodiment of the present disclosure.

FIG. 4B is a sectional view of the stretchable device according to the second variation of the second embodiment of the present disclosure.

FIG. 5A is a sectional view of a stretchable device according to a third variation of the second embodiment of the present disclosure.

FIG. 5B is a sectional view of the stretchable device according to the third variation of the second embodiment of the present disclosure.

FIG. 6 is a sectional view of a stretchable device according to a fourth variation of the second embodiment of the present disclosure.

FIG. 7 is a partial sectional view of a stretchable device according to a third embodiment of the present disclosure.

FIG. 8 is a partial sectional view of a stretchable device according to a first variation of the third embodiment of the present disclosure.

FIG. 9 is a partial sectional view of a stretchable device according to a second variation of the third embodiment of the present disclosure.

### DESCRIPTION OF THE PREFERRED EMBODIMENTS

Hereinafter, an embodiment of the present disclosure will be described in detail with reference to the drawings. In each embodiment, a difference from description before the embodiment will be mainly described. Particularly, similar functions and effects achieved by similar configurations will not be mentioned sequentially for each embodiment. Among constituent elements in an embodiment below, a constituent element not described in an independent claim is described as an optional constituent element. Further, size and a ratio of size of constituent elements illustrated in the drawings are not necessarily strict. Further, in the drawings, substantially the same configurations are denoted by the same reference numerals, and redundant description may be omitted or simplified.

### First Embodiment

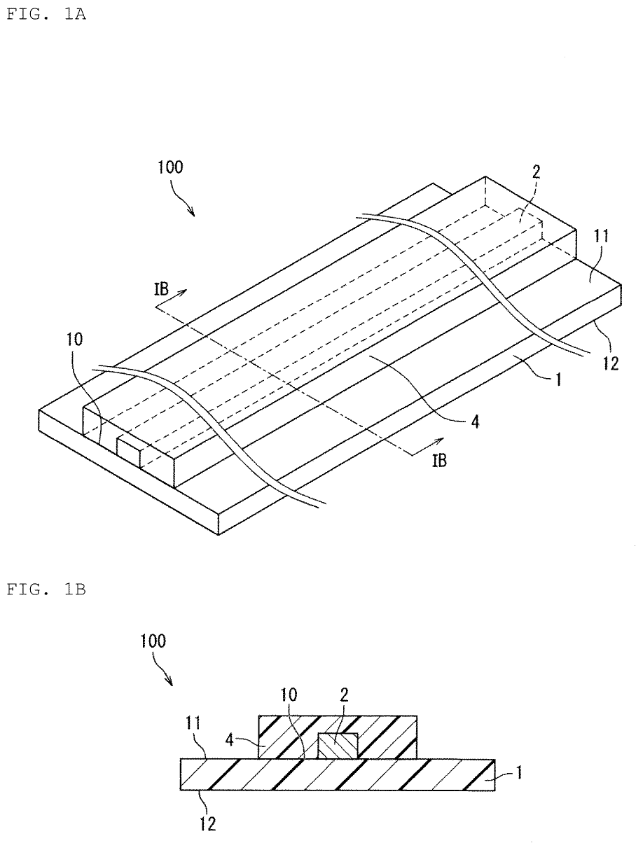

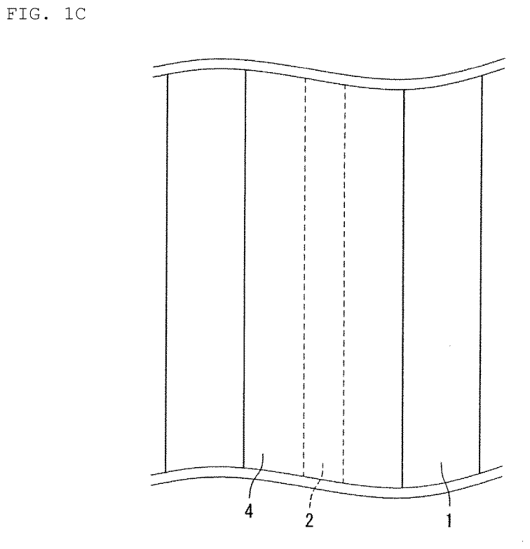

The structure of a stretchable device 100 will be described with reference to FIGS. 1A, 1B, and 1C. FIG. 1A is a perspective view schematically illustrating a stretchable device according to a first embodiment. FIGS. 1B and 1C are a sectional view taken along line IB-IB and a top view of FIG. 1A. Note that the sectional view in the present specification is a section perpendicular to an extending direction of a stretchable wiring. Also in actual comparison, it can be confirmed by the above-described sectional view at an arbitrary position extending in one direction of the stretchable wiring.

The stretchable device 100 includes a stretchable substrate 1, a stretchable wiring 2, and a first cover layer 4.

Hereinafter, the arrangement of these constituent elements will be described with reference to FIGS. 1B and 1C. As illustrated in FIGS. 1B and 1C, the stretchable substrate 1 has a first principal surface 11 and a second principal surface 12. The stretchable wiring 2 is provided on the first principal surface 11 of the stretchable substrate 1 and contains a resin as described later. Specifically, the stretchable wiring 2 is routed on the first principal surface 11 of the stretchable substrate 1. The first cover layer 4 is provided so as to cover at least a part of the stretchable wiring 2. The fact that the first cover layer 4 covers at least a part of the stretchable wiring 2 means that the outermost surface of the stretchable wiring 2 is covered as illustrated in FIG. 1B.

In the present specification, “on” refers to the first principal surface 11 side in a thickness direction of the stretchable substrate 1, and may not coincide with the upper and lower sides when the stretchable device 100 is used. Note that the shape of the stretchable device 100 is not particularly limited. In FIG. 1B, the extending direction of the stretchable wiring 2 and the longitudinal direction of the stretchable device 100 coincide with each other, but may not coincide with each other. For the sake of clarity, in FIG. 1A, only the wiring extending in a specific direction is illustrated, but the stretchable wiring 2 may not extend in one direction.

The stretchable substrate 1 is a sheet-shaped or film-shaped stretchable substrate, which is made from, for example, a resin material having stretchability. Examples of the resin material include thermoplastic polyurethane. The thickness of the stretchable substrate 1 is not particularly limited, but is preferably 1 mm or less, more preferably 100 μm or less, still more preferably 50 μm or less from the viewpoint of preventing stretchability of a surface of a living body from being impaired when the stretchable substrate 1 is attached to the living body. Further, the thickness of the stretchable substrate 1 is preferably 1 μm or more.

The stretchable wiring 2 contains conductive particles and a resin. Examples of the stretchable wiring 2 include a mixture of metal powder of Ag, Cu, Ni, and the like as the conductive particles and an elastomer-based resin such as a silicone resin. The average particle size of the conductive particles is not particularly limited, but is preferably 0.01 μm to 10 μm. The shape of the conductive particles is preferably spherical.

The thickness of the stretchable wiring 2 is not particularly limited, but is preferably 100 μm or less, more preferably 50 μm or less. The thickness of the stretchable wiring 2 is preferably 0.01 μm or more. The line width of the stretchable wiring 2 is not particularly limited, but is preferably 0.1 μm or more and more preferably 10 mm or less. The shape and number of the stretchable wirings 2 are not particularly limited.

The first cover layer 4 may be formed of a resin material having stretchability. For example, the first cover layer 4 is formed of an ionomer-based resin, a polyester-based resin, a styrene-based resin, an olefin-based resin, an epoxy-based resin, a urethane-based resin, an acrylic resin, or a silicone-based resin, and is preferably formed of a urethane-based resin. Examples of the urethane-based resin include thermoplastic polyurethane (TPU). Examples of the styrene-based resin include styrene-butadiene-styrene copolymer resin (SBS). Note that the first cover layer 4 may be configured by a plurality of members.

In the present embodiment, a total organic carbon concentration in an extraction liquid when the stretchable device 100 (which may also be referred to as a stretchable wiring substrate) is immersed in ultrapure water for 24 hours is 15 mg/L or less.

The above measurement was performed by a measurement method described later. Note that, all the total organic carbon concentrations described in the present specification are measured by the same method.

When a material as exemplified as the stretchable wiring 2 is used, biocompatibility may be deteriorated, and inflammation such as rash may occur. In this regard, in the present embodiment, since the first cover layer is provided, the ratio of all organic substances exposed to the outside can be limited to a certain value or less.

In the present embodiment, since the total organic carbon concentration in the extraction liquid when this stretchable device 100 is immersed in ultrapure water for 24 hours is set to 15 mg/L or less, a cytotoxicity value (cloning efficiency) derived from an organic substance can be kept within a predetermined standard value defined by ISO.

Specifically, when the total organic carbon concentration is 15 mg/L or less, the cloning efficiency measured by ISO10993-5 extraction-colony formation method can be 70% or more evaluated as having no cytotoxicity (no risk of biological adverse effects). Thereby, according to the stretchable device according to one embodiment of the present disclosure, biocompatibility can be improved.

That is, since the first cover layer 4 covers at least a part of the stretchable wiring 2, leakage of an organic component having toxicity and contact of a human body can be suppressed. It is preferable to cover the entire stretchable wiring 2. Note that the “entire” refers to the entire outer surface in a region that may come into contact with the human body when exposed. In a portion or the like where the stretchable wiring 2 is connected to an electronic component or another wiring, there may be a region where the first cover layer 4 is not disposed on the stretchable wiring 2.

A relationship between the total number of carbon atoms and biocompatibility is as shown in Table 1. As shown in Table 1, when the total organic carbon concentration (Tt) in the extraction liquid of the stretchable device 100 is 15 mg/L or less (Examples 1 to 6), cytotoxicity is 70% or more, and it can be confirmed that cytotoxicity is suppressed. On the other hand, when Tt is more than 15 mg/L (Comparative Examples 1 to 3), cytotoxicity is less than 70%.

From the above, the ratio of all organic substances exposed to the outside by providing the first cover layer can be limited to a certain value or less. Specifically, when Tt is 15 g/L or less, the cytotoxicity value (cloning efficiency) derived from an organic substance can be kept at a predetermined standard value defined by ISO or less. This makes it possible to provide a stretchable device having high biocompatibility.

The total organic carbon concentration (Tc) in the extraction liquid of the first cover layer 4 is preferably 10 mg/L or less. By providing such a first cover layer 4, biocompatibility can be further improved.

When Tc is 10 mg/L or less, the total organic carbon concentration (Tt) is easily set to 15 mg/L or less, and it is possible to make it difficult to affect the toxicity derived from an organic substance contained in the first cover layer itself.

The elastic modulus of the first cover layer 4 is preferably lower than the elastic modulus of the stretchable substrate 1. Since the stretchable device 100 expands and contracts at the time of use, when a member having a high elastic modulus is used, there is possibility that discomfort is given to a human body during stretching. By setting the elastic modulus of the first cover layer 4 to be lower than the elastic modulus of the stretchable substrate 1, discomfort felt by a user at the time of using the stretchable device 100 can be reduced.

Note that the method for measuring the elastic modulus is not particularly limited, and examples thereof include dynamic viscoelasticity measurement. When the first cover layer 4 is configured by a plurality of members, the measurement is performed in the same manner, and the average value is compared.

The elastic modulus of the first cover layer 4 is more preferably 1.8×10\hat{ }8 Pa or less and 1.0×10\hat{ }6 or more. By setting the elastic modulus of the first cover layer 4 within the above range, discomfort felt by a user can be further suppressed. More specifically, when the elastic modulus of the first cover layer 4 is too large, there is a possibility that expansion and contraction may be hindered during stretching. When the elastic modulus of the first cover layer 4 is too small, the first cover layer 4 is easily deformed, so that there is a possibility that an organic component leaks out or unnecessary deformation occurs at the time of use.

### Second Embodiment

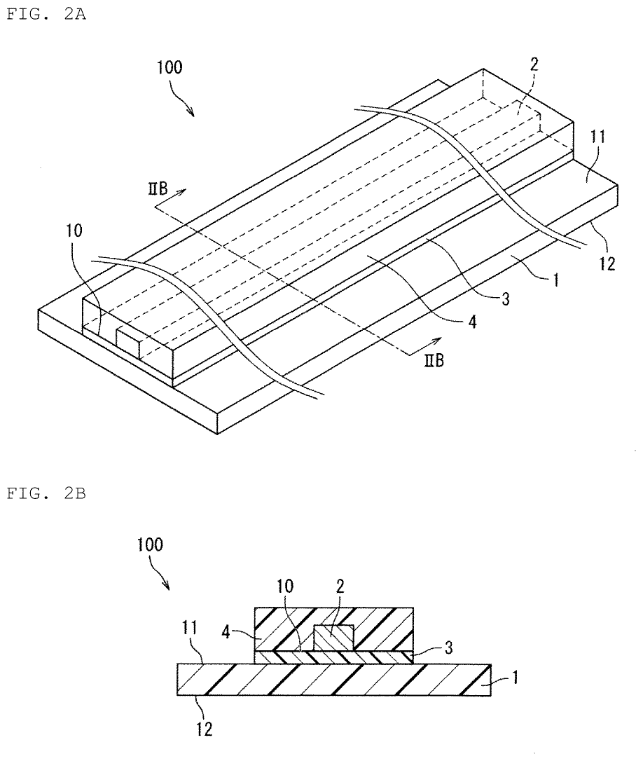

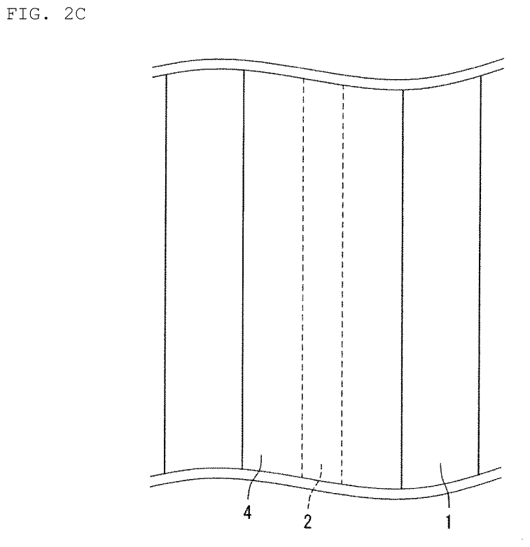

A structure of a stretchable device 100 according to a second embodiment will be described with reference to FIGS. 2A, 2B, and 2C. FIG. 2A is a perspective view schematically illustrating a stretchable device according to the second embodiment. FIGS. 2B and 2C are a sectional view taken along line IIB-IIB and a top view of FIG. 2A. Note that the sectional view in the present specification is a section perpendicular to an extending direction of a stretchable wiring. Also in actual comparison, it can be confirmed by the above-described sectional view at an arbitrary position extending in one direction of the stretchable wiring.

The second embodiment is different from the first embodiment in that the stretchable device 100 further includes a resin layer 3. In the second embodiment, the resin layer 3 is provided so as to be in contact with at least a part of the stretchable wiring 2. At this time, the first cover layer 4 is provided so as to cover the stretchable wiring 2 and at least a part of an external principal surface 10 of the resin layer 3.

In the present specification, “the resin layer 3 is in contact with at least a part of the stretchable wiring 2” means that the resin layer 3 is in contact with at least a part of the surface of the stretchable wiring 2. When the stretchable wiring 2 has a rectangular shape as illustrated in FIGS. 2B and 2C, the resin layer 3 is in contact with at least a part of the upper surface, the lower surface, and both side surfaces. Note that the stretchable wiring 2 is not limited to a rectangular shape as described above.

In the present specification, the “outer side” refers to a side relatively far from the stretchable substrate 1, and may not coincide with the outer side in actual use. The fact that the first cover layer 4 covers the stretchable wiring 2 and at least a part of the external principal surface 10 of the resin layer 3 means that the stretchable wiring 2 and the outermost surface of the resin layer 3 are covered as illustrated in FIG. 2B.

Hereinafter, the arrangement of these constituent elements will be specifically described with reference to FIGS. 2B and 2C. As illustrated in FIGS. 2B and 2C, the resin layer 3 is provided on the first principal surface 11 of the stretchable substrate 1, and the stretchable wiring 2 is provided on the resin layer 3.

By disposing the resin layer 3, entry of moisture into the stretchable wiring 2 can be suppressed. When moisture enters the stretchable wiring 2, ion migration occurs, and the wiring may be short-circuited. By suppressing entry of moisture into the stretchable wiring 2, reliability of the wiring can be improved.

The resin layer 3 is a resin formed by printing. More specifically, the resin layer 3 is preferably a resin material or a mixture of a resin material and an inorganic material, and examples of the resin material include elastomer-based such as urethane-based, styrene-based, olefin-based, silicone-based, fluorine-based, nitrile rubber, latex rubber, vinyl chloride, ester-based, and amide-based resin, and epoxy, phenol, acrylic, polyester, imide-based, rosin, cellulose, polyethylene terephthalate-based, polyethylene naphthalate-based, and polycarbonate-based resin. Note that the resin layer 3 may not be a single material.

The resin layer 3 preferably covers the upper surface of the stretchable wiring 2, and more preferably covers the side surface. When each surface of the stretchable wiring 2 is exposed, there is a possibility that moisture enters, so that entry of moisture can be further suppressed by covering each surface with the resin layer 3.

The resin layer 3 is preferably disposed between the stretchable substrate 1 and the stretchable wiring 2. In other words, the surface of the stretchable wiring 2 closest to the stretchable substrate 1 is preferably in contact with the resin layer 3. When the stretchable wiring 2 and the stretchable substrate 1 are in contact with each other, moisture absorbed by the stretchable substrate 1 may enter from the contact portion. By disposing the resin layer 3 between the stretchable substrate 1 and the stretchable wiring 2, entry of moisture into the stretchable wiring 2 can be further suppressed.

The resin layer 3 preferably covers the entire first principal surface 11 of the stretchable substrate. In a case where the stretchable substrate 1 and the stretchable wiring are in contact with each other as described above, when the stretchable substrate 1 absorbs moisture, the moisture may move to the stretchable wiring 2. The resin layer 3 can suppress entry of moisture from the first principal surface 11.

As described above, the resin layer 3 is used for the purpose of suppressing entry of moisture into the stretchable wiring 2. However, when a material as exemplified as the stretchable wiring 2 or the resin layer 3 is used, biocompatibility may be deteriorated, and inflammation such as rash may occur. In this regard, since the first cover layer 4 covers the stretchable wiring 2 and at least a part of the external principal surface 10 of the resin layer 3, leakage of an organic component having toxicity and contact of a human body can be suppressed. It is preferable to cover the stretchable wiring 2 and the entire external principal surface 10 of the resin layer 3.

Note that the arrangement of the resin layer 3 is not limited to that as in FIG. 2B. As illustrated in FIG. 2B, the resin layer may be provided so as to cover a part of the stretchable substrate 1, or may be disposed only in a region overlapping the stretchable wiring 2 in top view. Alternatively, the resin layer 3 may be disposed so as to be in contact only with the side surface of the stretchable wiring 2.

The first cover layer 4 does not need to be in contact with the stretchable wiring 2 and the external principal surface 10 of the resin layer 3. Specifically, when the resin layer 3 is disposed only in a region overlapping the stretchable wiring, the first cover layer may cover the stretchable wiring 2 or the external principal surface of the resin layer 3. That is, when the stretchable wiring 2 is disposed on the upper surface of the resin layer 3, only the upper surface of the stretchable wiring 2 may be covered, and when the resin layer 3 is disposed on the upper surface of the stretchable wiring 2, only the upper surface (corresponding to the external principal surface 10) of the resin layer 3 may be covered. In other words, it means that the stretchable wiring 2 and the upper surface of the resin layer 3 are not exposed.

### First Variation of Second Embodiment

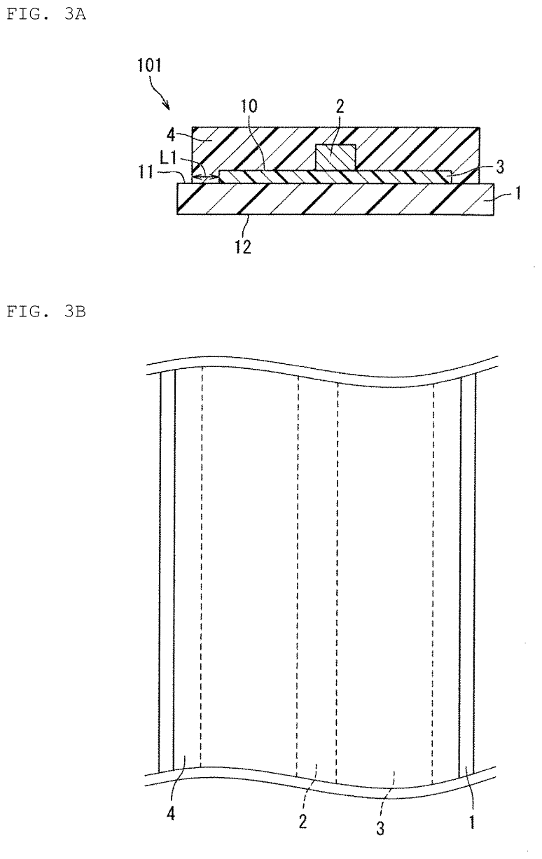

FIGS. 3A and 3B are a partial sectional view and a top view of a stretchable device 101 according to a first variation of the second embodiment, respectively. The first variation of the second embodiment will be described with reference to FIGS. 3A and 3B. The stretchable device 101 is different from the stretchable device 100 according to the second embodiment in the arrangement of the first cover layer 4.

In the width direction of the stretchable wiring 2, the dimension of the first cover layer 4 is larger than the dimension of the resin layer 3. Specifically, the first cover layer 4 preferably covers a range of 1 mm or more from both ends of the resin layer 3 in the width direction of the stretchable wiring. Specifically, it is preferable to cover a region indicated by the double-headed arrow L1 in the drawing.

When the dimension of the first cover layer 4 is larger than the dimension of the resin layer 3, it is possible to suppress exposure of a member containing an organic component and leakage of the organic component due to positional displacement by expansion and contraction at the time of use.

The first cover layer 4 preferably covers the stretchable wiring 2 and a part of the external principal surface 10 of the resin layer 3 and a side surface continuous with the external principal surface 10, and more preferably covers entire side surface of the resin layer 3.

With the configuration as described above, leakage of the organic component from the stretchable wiring 2 and the side surface of the resin layer 3 can be suppressed.

The first cover layer 4 is preferably in contact with the first principal surface 11 of the stretchable substrate 1.

As illustrated in FIGS. 3A and 3B, since the first cover layer 4 covers the stretchable wiring 2 and the external principal surface 10 of the resin layer 3 and is in contact with the first principal surface 11 of the stretchable substrate 1, it is possible to more reliably cover each surface of the stretchable wiring 2 and the resin layer 3. Since the stretchable substrate 1 and the first cover layer 4 are in contact with each other, the risk of positional displacement can be further reduced. That is, leakage of the organic component can be more reliably suppressed.

### Second Variation of Second Embodiment

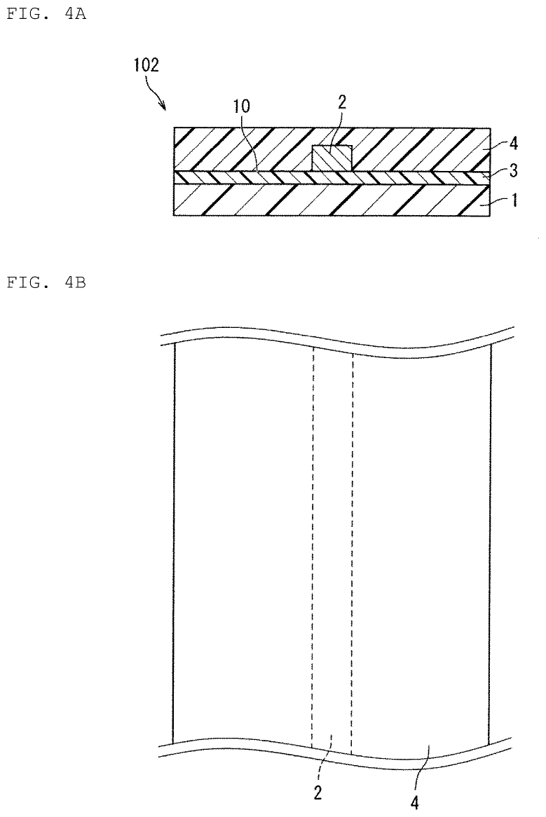

FIGS. 4A and 4B are a partial sectional view and a top view of a stretchable device 102 according to a second variation of the second embodiment, respectively. The second variation of the second embodiment will be described with reference to FIGS. 4A and 4B. The stretchable device 102 is different from the stretchable device 100 according to the second embodiment in the arrangement of the resin layer 3.

In the width direction of the stretchable wiring 2, the dimension of the resin layer 3 is equal to or more than the first principal surface 11.

With the configuration as described above, as illustrated in FIG. 4A, the resin layer 3 covers the entire first principal surface 11 of the stretchable substrate 1. That is, entry of moisture from the first principal surface 11 of the stretchable substrate 1 can be reduced, and occurrence of ion migration of the stretchable wiring 2 can be suppressed.

Note that, although increasing the area of the resin layer 3 may cause a decrease in biocompatibility, as illustrated in FIGS. 4A and 4B, the first cover layer 4 covers the entire first principal surface of the resin layer 3, so that occurrence of ion migration of the stretchable wiring 2 can be suppressed, and the stretchable device 102 having no cytotoxicity can be provided.

### Third Variation of Second Embodiment

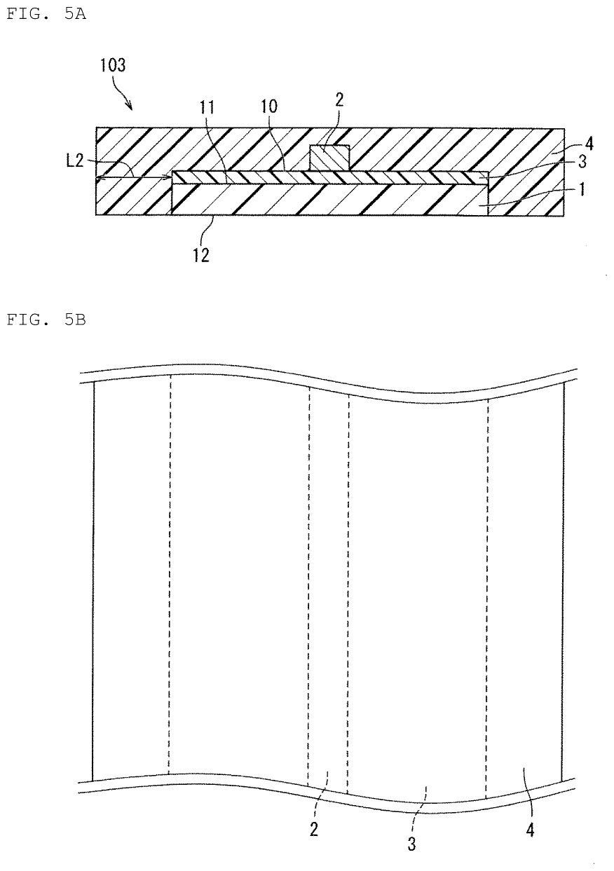

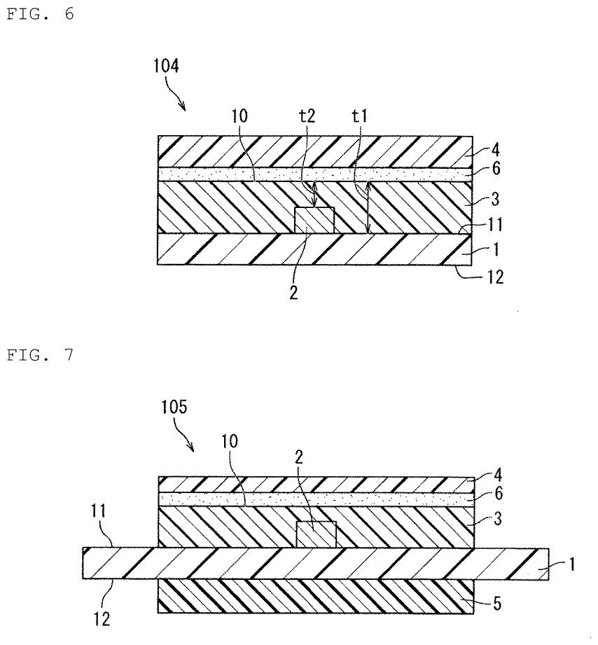

FIGS. 5A and 5B are a partial sectional view and a top view of a stretchable device 103 according to a third variation of the second embodiment, respectively. The third variation of the second embodiment will be described with reference to FIGS. 5A and 5B. The stretchable device 102 is different from the stretchable device 100 according to the second embodiment in the arrangement of the first cover layer 4.

In the width direction of the stretchable wiring 2, the dimension of the first cover layer 4 is larger than the dimension of the stretchable substrate 1. Specifically, the first cover layer 4 preferably covers a range of 1 mm or more from both ends of the stretchable substrate 1 in the width direction of the stretchable wiring. Specifically, a region indicated by the double-headed arrow L2 in the drawing is preferably 1 mm or more.

With the configuration as described above, leakage of the organic component due to positional displacement during stretching at the time of use can be suppressed, so that the cytotoxicity value (cloning efficiency) can be easily kept within a predetermined standard value defined by ISO. This makes it possible to further improve biocompatibility.

As described above, the stretchable wiring 2 and the resin layer 3 have an organic component having cytotoxicity, but the stretchable substrate 1 may also have an organic component having cytotoxicity.

That is, the first cover layer 4 covers the stretchable substrate 1, so that leakage of the organic component from the stretchable substrate 1 can be suppressed.

The first cover layer 4 preferably covers the first principal surface 11 of the stretchable substrate 1 and a side surface continuous with the first principal surface 11, and more preferably covers the entire side surface continuous with the first principal surface 11.

As illustrated in FIG. 5A, by covering the first principal surface 11 and the side surface connecting the first principal surface 11 and the second principal surface 12, leakage of the organic component from the side surface of the stretchable substrate 1 can be suppressed.

The thickness of the first cover layer 4 is preferably 40 μm or more.

When the thickness of the first cover layer 4 is thin as Comparative Example 3 in Table 1, an organic component having cytotoxicity easily leaks out. By setting the thickness of the first cover layer to 40 μm or more, leakage of the organic component can be suppressed.

The thickness of the first cover layer 4 is still more preferably 50 μm or more.

Alternatively, by further increasing the thickness of the first cover layer, specifically, to 50 μm or more, leakage of the organic component can be more reliably suppressed.

The thickness of the first cover layer 4 is preferably 200 μm or less. As described above, when the thickness of the first cover layer 4 is increased, leakage of the organic component can be suppressed. On the other hand, when the thickness of the first cover layer is increased, the stretching performance is deteriorated, and the possibility of giving discomfort at the time of use increases.

By setting the thickness of the first cover layer 4 to 40 μm to 200 μm, leakage of the organic component can be suppressed, and the possibility of giving discomfort at the time of use can be reduced.

Note that, when there are portions having different distances and thicknesses in the width direction as described above, the average value is taken as the thickness of the first cover layer. These values can be measured by a dial gauge or the like specified in JIS B 7503.

### Fourth Variation of Second Embodiment

FIG. 6 is a partial sectional view of a stretchable device 104 according to a fourth variation of the second embodiment. The fourth variation of the second embodiment will be described with reference to FIG. 6. The stretchable device 104 is different from the stretchable device 100 according to the second embodiment in the arrangement of the resin layer 3 and the configuration of the first cover layer 4.

As illustrated in FIG. 6, the resin layer 3 may cover the upper surface and the side surface of the stretchable wiring 2. As described above, a region disposed between the stretchable wiring 2 and the stretchable substrate 3 may be further included.

In this way, by disposing the resin layer 3, each surface of the stretchable wiring 2 is covered, and ion migration of the stretchable wiring 2 can be more reliably suppressed.

The thickness of a region of the resin layer 3 overlapping the stretchable wiring 2 is smaller than the thickness of a region of the resin layer 3 not overlapping the stretchable wiring 2.

Specifically, the dimension of the double-headed arrow t1 illustrated in FIG. 6 is larger than the dimension of the double-headed arrow t2. By providing the resin layer in this manner, the region overlapping the stretchable wiring 2 and the region not overlapping the stretchable wiring 2 can be flattened.

When the resin layer 3 is formed with a constant thickness as illustrated in FIGS. 2B, 3A, 4A, and 5A, a difference in thickness occurs between the region overlapping the stretchable wiring 2 and the region not overlapping the stretchable wiring 2. The difference in thickness may cause discomfort at the time of use. Since the stretching performance is different, there is a possibility that it is becomes a starting point of breakage during stretching.

As illustrated in FIGS. 2B, 3A, 4A, and 5A, the entire flattening may be performed by changing the thickness of the first cover layer 4, but it may be difficult to change the thickness depending on the member constituting the first cover layer 4. That is, by disposing the resin layer 3 as described above, it is possible to reliably suppress ion migration of the stretchable wiring 2 and to realize flattening of the stretchable device 104 without limiting the member of the first cover layer.

It is preferable that a surface of the first cover layer 4 closest to the stretchable substrate 1 has adhesiveness.

The surface of the first cover layer 4 closest to the stretchable substrate 1 is namely a surface in contact with the stretchable substrate 1, the stretchable wiring 2, and the resin layer 3. The surface of the first cover layer 4 closest to the stretchable substrate 1 is the innermost principal surface of the first cover layer 4.

As described above, the stretchable device has a risk of positional displacement due to expansion and contraction at the time of use. Since the first cover layer 4 has adhesiveness at a portion in contact with the stretchable substrate 1, the stretchable wiring 2, and the resin layer 3, a risk of positional displacement can be reduced, and leakage of the organic component associated therewith can be suppressed.

As a structure having adhesiveness, when the first cover layer 4 is configured by a plurality of members, the adhesive layer may be used as a member closest to the stretchable substrate 1, or the first cover layer 4 may be configured by a single member having adhesiveness. The first cover layer 4 may be configured by a member having no adhesiveness, and an adhesive may be applied to a surface of the first cover layer 4 closest to the stretchable substrate 1.

The adhesive layer and the adhesive can be used without particular limitation as long as they can be used by being laminated on a general stretchable substrate, and examples of the adhesive layer include reactive adhesives such as an epoxy resin-based adhesive, a silicone-based adhesive, and a urethane-based adhesive, and melt-solidifying adhesives such as an acrylic resin-based adhesive and a synthetic rubber-based adhesive.

It is still more preferable that a surface of the first cover layer 4 closest to the stretchable substrate 1 has bonding adhesiveness. It can be realized by using the adhesive as a bonding adhesive or using the adhesive layer as a bonding adhesive layer having the above-described structure having adhesiveness. Since the bonding adhesive and the bonding adhesive layer have high connection reliability, it is possible to prevent the substrate from being deteriorated by utilizing excessive heat or UV energy for reacting after grounding required for the adhesive and the adhesive layer. Specific examples thereof include bonding adhesives such as rubber-based, acryl-based and silicone-based bonding adhesives, which are pressure-sensitive adhesives. FIG. 6 illustrates an example in which a first bonding adhesive layer 6 is newly provided.

With the configuration as described above, a risk of positional displacement can be further reduced, and leakage of the organic component associated therewith can be suppressed.

### Third Embodiment

FIG. 7 is a partial sectional view of a stretchable device 105 according to a third embodiment. The third embodiment will be described with reference to FIG. 7. The stretchable device 105 is different from the stretchable device 100 according to the second embodiment in including a second cover layer 5.

The stretchable device 105 further includes the second cover layer 5 covering the second principal surface 12 of the stretchable substrate 1.

As described above, the stretchable substrate 1 also has an organic component. Therefore, in a state where the second principal surface 12 is exposed, the organic component may leak out. By covering the second cover layer 5, the exposed portion of the second principal surface 12 is reduced, so that leakage of the organic component from the second principal surface 12 side of the stretchable substrate 1 can be suppressed.

Similarly to the first cover layer 4, in the width direction of the stretchable wiring 2, the dimension of the second cover layer 5 is preferably larger than the dimension of the second principal surface 12.

It is preferable that the second cover layer 5 covers a side surface connecting the first principal surface 11 and the second principal surface. Note that it is preferable that at least one of the first cover layer 4 and the second cover layer 5 covers the side surface.

Since the effects of the above configuration are similar to those of the first cover layer 4, the description thereof will be omitted.

The second cover layer 5 may be formed of a resin material having stretchability. For example, the first cover layer 4 is formed of an ionomer-based resin, a polyester-based resin, a styrene-based resin, an olefin-based resin, an epoxy-based resin, a urethane-based resin, an acrylic resin, or a silicone-based resin, and is preferably formed of a urethane-based resin. Examples of the urethane-based resin include thermoplastic polyurethane (TPU). Examples of the styrene-based resin include styrene-butadiene-styrene copolymer resin (SBS). Note that the second cover layer 5 may be configured by a plurality of members.

The second cover layer 5 may be configured by the same member as the first cover layer 4, or may be configured by a different member.

By forming the first cover layer 4 and the second cover layer 5 with the same member, the first cover layer 4 and the second cover layer 5 expand and contract equally during stretching, so that the connection reliability of the first cover layer 4 and the second cover layer 5 can be increased. In the case of the same member, it is easy to form the cover layers. Note that the first cover layer 4 and the second cover layer 5 may be different members. By selecting a material suitable for the first cover layer 4 and the second cover layer 5, the bonding strength of each layer can be optimized.

Similarly to the first cover layer 4, the total organic carbon concentration in the extraction liquid of the second cover layer 5 is preferably 10 mg/L or less. The elastic modulus of the second cover layer 5 is preferably lower than the elastic modulus of the stretchable substrate 1, and more preferably 1.0×10\hat{ }8 Pa or less and 1.0×10\hat{ }6 or more.

The thickness of the second cover layer 5 is preferably 40 μm or more and more preferably 50 μm or more. Similarly, the thickness of the second cover layer is more preferably 200 μm or less.

Since the effects of the above configuration are similar to the effects in the first cover layer 4, the description thereof will be omitted.

Note that, when the stretchable device includes the second cover layer 5, the total thickness of the first cover layer 4 and the second cover layer 5 is preferably 80 μm to 400 μm. By disposing the first cover layer 4 and the second cover layer 5 as described above, leakage of the organic component can be suppressed, and discomfort at the time of use can be reduced.

In FIG. 7, the first cover layer 4 and the second cover layer 5 have the same dimension in the width direction of the stretchable wiring 2, but may have different dimensions. As illustrated in FIG. 7, the thickness of the first cover layer 4 and the thickness of the second cover layer 5 may be different from each other as illustrated in FIG. 7, or may be the same.

### First Variation of Third Embodiment

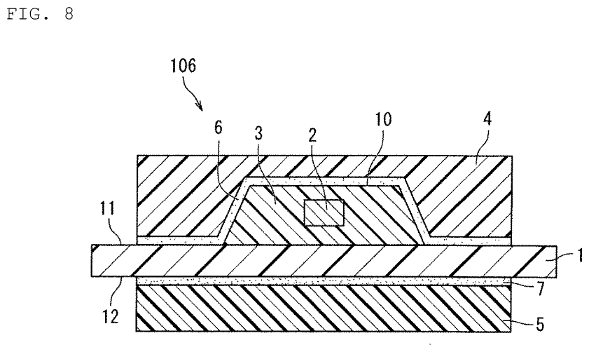

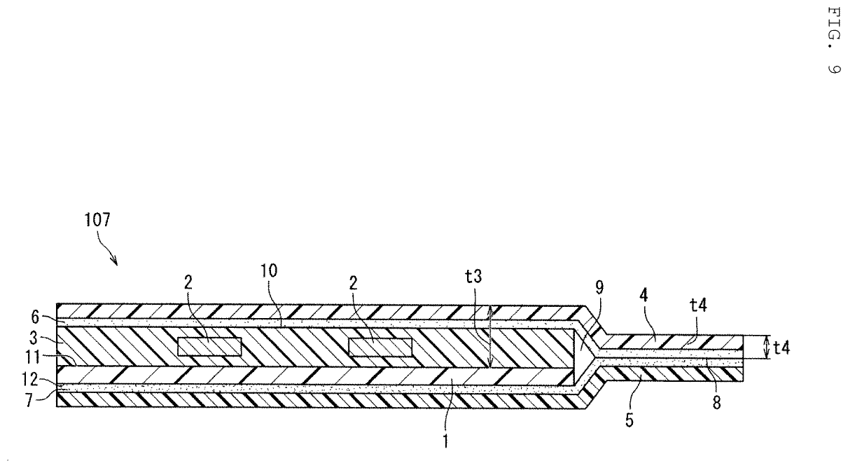

FIG. 8 is a partial sectional view of a stretchable device 106 according to a first variation of the third embodiment. The first variation of the third embodiment will be described with reference to FIG. 8. The stretchable device 106 is different from the stretchable device 105 according to the third embodiment in including a second bonding adhesive layer 7.

It is preferable that a surface of the second cover layer 5 closest to the stretchable substrate has adhesiveness.

A surface of the second cover layer 5 closest to the stretchable substrate 1 is the innermost principal surface facing the second principal surface of the stretchable substrate 1. In the present embodiment, the surface of the second cover layer 5 closest to the stretchable substrate 1 is a surface in contact with the second principal surface of the stretchable substrate 1. Note that, when the stretchable wiring 2 and the resin layer 3 are provided on the second principal surface 12, the surface of the second cover layer 5 closest to the stretchable substrate 1 is also a surface in contact with the stretchable wiring 2 and the resin layer 3.

As a structure having adhesiveness, when the second cover layer 5 is configured by a plurality of members, the adhesive layer may be used as a member closest to the stretchable substrate 1, or the second cover layer 5 may be configured by a single member having bonding adhesiveness. The second cover layer 5 may be configured by a member having no adhesiveness, and an adhesive may be applied to a surface of the second cover layer 5 closest to the stretchable substrate 1.

The adhesive layer and the adhesive can be used without particular limitation as long as they can be used by being laminated on a general stretchable substrate, and examples of the adhesive layer include reactive adhesives such as an epoxy resin-based adhesive, a silicone-based adhesive, and a urethane-based adhesive, and melt-solidifying adhesives such as an acrylic resin-based adhesive and a synthetic rubber-based adhesive. Examples thereof further include bonding adhesives such as rubber-based, acryl-based and silicone-based bonding adhesives, which are pressure-sensitive adhesives. FIG. 8 illustrates an example in which the second bonding adhesive layer 7 is newly provided.

As a structure having adhesiveness, when the first cover layer 4 is configured by a plurality of members, the adhesive layer may be used as a member closest to the stretchable substrate 1, or the first cover layer 4 may be configured by a single member having adhesiveness. The first cover layer 4 may be configured by a member having no adhesiveness, and an adhesive may be applied to a surface of the first cover layer 4 closest to the stretchable substrate 1.

It is still more preferable that a surface of the second cover layer 5 closest to the stretchable substrate 1 has bonding adhesiveness. It can be realized by using the adhesive as a bonding adhesive or using the adhesive layer as a bonding adhesive layer having the above-described structure having adhesiveness. Since the bonding adhesive and the bonding adhesive layer have high connection reliability, it is possible to prevent the substrate from being deteriorated by utilizing excessive heat or UV energy for reacting after grounding required for the adhesive and the adhesive layer. Specific examples thereof include bonding adhesives such as rubber-based, acryl-based and silicone-based bonding adhesives, which are pressure-sensitive adhesives.

Note that, since the first cover layer 4 and the second cover layer 5 may be configured by different members as described above, it is needless to say that the structure for having bonding adhesiveness may be different.

Since the surface of the second cover layer closest to the stretchable substrate 1 has bonding adhesiveness, connection reliability between the second cover layer 5 and the second principal surface 12 can be enhanced, and leakage of the organic component due to positional displacement can be suppressed.

Since the arrangement of the first bonding adhesive layer and the second bonding adhesive layer varies depending on the arrangement of the stretchable wiring 2 and the resin layer 3, the first bonding adhesive layer 6 and the second bonding adhesive layer 7 do not need to have the same shape as illustrated om FIG. 8. The same applies to the case of adopting other methods for having bonding adhesiveness.

### Second Variation of Third Embodiment

FIG. 9 is a partial sectional view of the stretchable device 107 according to a second variation of the third embodiment. The second variation of the third embodiment will be described with reference to FIG. 9. The stretchable device 107 is different from the stretchable device 105 according to the third embodiment in the arrangement of the first cover layer 4 and the second cover layer 5.

Specifically, the first cover layer 4 and the second cover layer 5 are preferably in contact with each other in a region not overlapping the stretchable substrate 1.

In the width direction of the stretchable wiring 2, the dimension of the second cover layer 5 is preferably larger than the dimension of the second principal surface 12, and it is preferable to cover a range of 1 mm or more from the end in the width direction of the stretchable wiring 2 of the second principal surface 12. Similarly to the first cover layer 4, by adopting the arrangement as described above, it is possible to suppress leakage of the organic component due to positional displacement accompanying expansion and contraction at the time of use.

When the dimension of the first cover layer 4 is larger than the dimension of the first principal surface 11 and the dimension of the second cover layer 5 is larger than the dimension of the second principal surface 12 in the width direction of the stretchable wiring 2, both the first cover layer 4 and the second cover layer 5 protrude from the stretchable substrate 1, so that the first cover layer 4 and the second cover layer 5 can be brought into contact with each other. In the case of the structure as described above, if the positional displacement of the stretchable substrate 1 occurs, the movement of the stretchable substrate 1 is suppressed at a connecting portion between the first cover layer 4 and the second cover layer 5. The stretchable substrate 1 and the side surfaces of the stretchable wiring 2 and the resin layer 3 can be more reliably covered. That is, leakage of the organic component can be more reliably suppressed.

It is more preferable that the innermost principal surface having adhesiveness of the first cover layer 4 and the innermost principal surface having adhesiveness of the second cover layer are in contact with each other in a region not overlapping the stretchable substrate 1.

In other words, the connecting portion between the first cover layer 4 and the second cover layer 5 described above is preferably a connection between surfaces having bonding adhesiveness.

FIG. 9 illustrates an example in which the first cover layer and the second cover layer have bonding adhesiveness by including the first bonding adhesive layer and the second bonding adhesive layer similarly to the above-described examples. As described above, the configuration in which the first cover layer 4 and the second cover layer 5 have bonding adhesiveness is not limited to the configuration as illustrated in FIG. 9.

In FIG. 9, a contact portion between the first cover layer 4 and the second cover layer 5 is illustrated as “8”. As illustrated in FIG. 9, the contact portion is preferably contact between surfaces having bonding adhesiveness.

Since the bonding adhesive layers are connected to each other, the possibility of positional displacement during stretching can be greatly reduced. That is, leakage of the organic component can be suppressed.

It is preferable that a plurality of contact portions exist between the first cover layer 4 and the second cover layer 5, and the stretchable substrate 1 is disposed between the plurality of contact portions in the width direction of the stretchable wiring 2.

With the configuration as described above, the periphery of the stretchable substrate 1, the stretchable wiring 2, and the resin layer 3 having an organic component is fully sealed by the first cover layer 4 and the second cover layer 5 when viewed in a section perpendicular to the extending direction of the stretchable wiring.

That is, leakage of the organic component can be greatly suppressed. Note that the first cover layer and the second cover layer 5 may have shapes along the stretchable substrate 1, the stretchable wiring 2, and the resin layer 3, and as illustrated in FIG. 9, a void 9 may be provided between the first and second cover layers and a member having an organic component.

It is preferable that a plurality of the stretchable wirings 2 facing away from each other are provided on the first principal surface 11 of the stretchable substrate 1, and the resin layer 3 is disposed between one of the stretchable wirings 2 and the other of the stretchable wirings 2 adjacent to each other.

Ion migration caused by entry of moisture occurs between the plurality of stretchable wirings 2 having different potentials. As illustrated in FIG. 9, by providing the resin layer 3 between the plurality of stretchable wirings in the width direction of the stretchable wiring 2, entry of moisture can be suppressed, and the possibility of occurrence of ion migration can be reduced. It is easy to ensure the overall flatness of the resin layer 3.

### EXAMPLES

Hereinafter, Examples will be described.

### (1) Sample Preparation (Examples 1 to 8 and Comparative Examples 1 to 4)

Examples 1 to 8 and Comparative Examples 1 to 4 are samples in which the configurations of the first cover layer and the second cover layer are changed or the presence or absence of the cover layer is different for the stretchable device described above. The configuration of each of the first cover layer and the second cover layer is shown in the lower four rows of Table 1 below. Note that Comparative Examples 1 and 4 are samples not including the first cover layer and the second cover layer. The thicknesses of the first cover layer and the second cover layer are average values of dimensions of the first cover layer and the second cover layer in the thickness direction of the stretchable substrate 1. The presence or absence of the adhesive indicates whether the innermost principal surfaces of the first cover layer and the second cover layer have adhesiveness. Note that, in this example, the presence or absence of adhesiveness is changed by disposing a bonding adhesive. The widths of the first cover layer and the second cover layer are obtained by comparing the dimensions of the stretchable substrate 1, the resin layer 3, and the first cover layer 4 in the width direction of the stretchable wiring 2. In Table 1, the stretchable substrate width described alone indicates that the dimensions of the first cover layer 4 and the second cover layer 5 are substantially the same as the width dimension of the stretchable substrate. In Table 1, the resin layer width indicates that the dimensions of the resin layer 3, the first cover layer 4, and the second cover layer 5 are substantially the same, the “resin layer width+1” indicates that the first cover layer 4 and the second cover layer 5 protrude from the end in the width direction of the resin layer 3 by 1 mm, and the “stretchable substrate width+1” indicates that the dimensions of the first cover layer 4 and the second cover layer 5 protrude from the width of the stretchable substrate 1 by 1 mm. The elastic modulus was measured by viscoelasticity, and the storage elastic modulus at 30° C. was measured. The member indicates a main member of each cover layer. Note that, in Examples 7 and 8, no resin layer is provided.

### (2) Sample Measurement Method

Extraction solvent: ultrapure water ※TOC value of ultrapure water alone=0.1 mg/L (lower limit of quantification) or less

Extraction condition: Leave to stand still for 24 hours in environment of 23° C.

Extraction operation: Into an extraction vessel, 40 cc of ultrapure water and a sheet-shaped sample of each level were put in a size of 50 mm×50 mm, and the sample was left to stand still for 24 hours in an environment of 23° C. to obtain an extraction solution.

Test operation: For the obtained extraction solution using each sample, the concentration (C mg/L) of total organic carbon (TOC) was calculated using TOC-VCSH (total organic carbon meter (TOC meter)) manufactured by SHIMADZU CORPORATION in accordance with JIS K 0805 by combustion oxidation-infrared TOC analysis in Section 22.1 of JIS K 0102.

### (3) Measurement Results (Examples 1 to 8 and Comparative Examples 1 to 4)

The measurement results are shown in the upper four rows of Table 1 below. Tt (entire TOC) (mg/L) is the result of measuring the stretchable device of each of Examples and variations by the above-described measurement method. Tc (TOC cover alone) (mg/L) is the result of measuring only the first cover layer 4 in each Example by the above-described measurement method. The cloning efficiency (%) is a result of measuring the cloning efficiency according to ISO10993-5 Annex. Regarding the presence or absence of toxicity, samples having cloning efficiency of 70% or more were evaluated as having no toxicity, and samples having cloning efficiency of less than 70% were evaluated as having toxicity.

TABLE 1

| | Example 1 | Example 2 | Example 3 | Example 4 | Example 5 | Example 6 |
|---|---|---|---|---|---|---|
| Tt (entire TOC) | 7.8 | 8.7 | 14.9 | 12.4 | 11.9 | 11.6 |
| (mg/L) | | | | | | |
| Tc (TOC cover | 0.3 | 1.2 | 4.2 | 5.8 | 5.8 | 5.8 |
| alone) (mg/L) | | | | | | |
| Cloning efficiency | 87 | 91 | 72 | 75 | 77 | 79 |
| (%) | | | | | | |
| Presence or absence | Absent | Absent | Absent | Absent | Absent | Absent |
| of toxicity | | | | | | |
| Thicknesses of | 50 | 50 | 40 | 55 | 55 | 55 |
| first and second | | | | | | |
| cover layers (μm) | | | | | | |
| Presence or absence | Absent | Absent | Present | Present | Present | Present |
| of adhesive | | | | | | |
| Widths of first and | Resin | Resin | Resin | Resin | Resin | Resin layer |
| second cover layers | layer | layer | layer | layer | layer | width + 2 |
| (mm) | width | width | width | width | width + 1 | Stretchable |
| | | | | | | substrate |
| | | | | | | width + 1 |
| Elastic modulus E′ | 1.8E+08 | 1.4E+07 | 7.0E+06 | 7.0E+06 | 7.0E+06 | 7.0E+06 |
| (Pa) @30° C. | | | | | | |
| (Whole or part) of | Olefin | Styrene | Urethane | Urethane | Urethane | Urethane |
| constituent members | | | | | | |
| of first and second | | | | | | |
| cover layers | | | | | | |

| | | | Comparative | Comparative | Comparative | Comparative |
|---|---|---|---|---|---|---|
| | Example 7 | Example 8 | Example 1 | Example 2 | Example 3 | Example 4 |
| Tt (entire TOC) | 5.6 | 6.5 | 21.6 | 159.8 | 16.6 | 17.5 |
| (mg/L) | | | | | | |
| Tc (TOC cover | 1.2 | 1.2 | — | 159.8 | 3.1 | — |
| alone) (mg/L) | | | | | | |
| Cloning efficiency | 95 | 90 | 37 | 0 | 63 | 55 |
| (%) | | | | | | |
| Presence or absence | Absent | Absent | Present | Present | Present | Present |
| of toxicity | | | | | | |
| Thicknesses of | 50 | 50 | No | 130 | 30 | No |
| first and second | | | cover | | | cover |
| cover layers (μm) | | | layer | | | layer |
| Presence or absence | Absent | Absent | Absent | Absent | Present | Absent |
| of adhesive | | | | | | |
| Widths of first and | Stretchable | Stretchable | — | — | Resin | — |
| second cover layers | substrate | substrate | | | layer | |
| (mm) | width | width | | | width | |
| Elastic modulus E′ | 1.4E+07 | 1.4E+07 | — | 2.8E+07 | 7.0E+06 | — |
| (Pa) @30° C. | | | | | | |
| (Whole or part) of | Styrene | Styrene | None | Acryl | Urethane | None |
| constituent members | | | | | | |
| of first and second | | | | | | |
| cover layers | | | | | | |

From the results of Comparative Examples 1 and 4, it can be confirmed that the sample without the first cover layer has cytotoxicity. From Comparative Examples 2 and 3, it can be confirmed that the sample having sufficiently large Tt (entire TOC) (mg/L) has cytotoxicity. Comparing Example 3 with Comparative Example 3, it can be confirmed that the sample has no cytotoxicity, that is, the sample is a stretchable device having high biocompatibility by setting Tt (entire TOC) (mg/L) to 15 mg/L.

Next, respective Examples are compared. Examples 1 and 2 have different elastic moduli. By setting the elastic modulus to 1.8×10\hat{ }8 Pa or less, it can be confirmed that the cloning efficiency is increased. Since the determination of cytotoxicity is made by cloning efficiency, the higher the cloning efficiency, the higher the biocompatibility.

In Examples 1 to 3, the configurations of the members are different. As shown in Examples 3 to 6, an elastomer film such as urethane on which a bonding adhesive layer is laminated can be selected as a main member of the first cover layer 4. As compared with a case where the film itself is bonded by the action of melting or reaction, such as a thermoplastic resin or a thermosetting resin, it is possible to suppress deterioration due to heat or UV irradiation by selecting an elastomer film, such as a urethane-based or styrene-based film, on which a bonding adhesive layer is laminated and performing a pressure-bonding treatment at normal temperature. Note that the first cover layer 4 may include other members such as a bonding adhesive layer in addition to the elastomer film. The elastomer film is preferably a member of the first cover layer 4 farthest from the stretchable substrate 1. The presence or absence of the bonding adhesive layer is different between Example 2 and Examples 3 to 6. As shown in Examples 3 to 6, an elastomer film such as urethane on which a bonding adhesive layer is laminated can be selected as a main member of the first cover layer 4. As compared with a film monolayer having an adhesion mechanism such as a thermoplastic resin, deterioration due to heat or deformation can be suppressed by selecting a laminate of urethane bonding adhesive layers.

The thicknesses of the first cover layer 4 and the second cover layer 5 are different between Example 3 and Example 4. By setting the thicknesses of the first cover layer 4 and the second cover layer 5 to 55 μm, it can be confirmed that the cloning efficiency is improved.

Example 4 is different from Example 5 in whether or not the first cover layer 4 and the second cover layer 5 protrude from the resin layer 3. By disposing the first cover layer 4 and the second cover layer 5 so as to protrude from the resin layer 3 as in Example 5, it can be confirmed that the cloning efficiency is improved.

Example 5 is different from Example 6 in whether or not the first cover layer 4 and the second cover layer 5 protrude from the stretchable substrate 1. By disposing the first cover layer 4 and the second cover layer 5 so as to protrude from the stretchable substrate 1 as in Example 6, it can be confirmed that the cloning efficiency is improved.

From Examples 2, 7, and 8, it can be confirmed that when the constituent member of the cover layer is styrene, the cloning efficiency exceeds 90% as compared with a case where the constituent member is olefin or urethane. When the constituent member of the cover layer is styrene and the width of the cover layer is the stretchable substrate width, it can be confirmed that Tt is less than 7.0.

Note that constituent elements other than the first cover layer are the same as the constituent elements other than the first cover layer 4 and the second cover layer 5 in the second variation of the third embodiment. The same applies to the effect, and thus the description thereof will be omitted.

### (4) Overall Discussion

As shown in Table 1, by setting Tt (entire TOC) (mg/L) to 15 mg/L or less, it can be confirmed that biocompatibility of the stretchable device can be improved. In the stretchable device of each sample, by covering the stretchable wiring 2 with the resin layer 3, entry of moisture can be prevented, and occurrence of a short circuit due to ion migration can be suppressed. That is, it is possible to provide a stretchable device in which a short circuit of a stretchable wiring is suppressed and biocompatibility is improved.

Note that each of the embodiments and variations is an example, and the present disclosure is not limited to each of the embodiments. Each drawing is an example of a constituent element, and does not limit a shape. Further, partial replacement or combination of configurations shown in different embodiments and variations is possible.

The present disclosure can adopt the following aspects.

<1> A stretchable device including: a stretchable substrate having a first principal surface and a second principal surface; a stretchable wiring on the first principal surface and containing a resin; and a first cover layer covering at least a part of the stretchable wiring, wherein a total organic carbon concentration in an extraction liquid when the stretchable device is immersed in ultrapure water for 24 hours is 15 mg/L or less.

<2> The stretchable device according to <1>, further including a resin layer in contact with at least a part of the stretchable wiring.

<3> The stretchable device according to <2>, wherein the first cover layer further covers at least a part of an external principal surface of the resin layer.

<4> The stretchable device according to any one of <1> to <3>, wherein the total organic carbon concentration in an extraction liquid when the first cover layer is immersed in ultrapure water for 24 hours is 10 mg/L or less.

<5> The stretchable device according to any one of <1> to <4>, wherein an elastic modulus of the first cover layer is smaller than an elastic modulus of the stretchable substrate.

<6> The stretchable device according to any one of <2> to <5>, wherein a dimension of the first cover layer is larger than a dimension of the resin layer in a width direction of the stretchable wiring.

<7> The stretchable device according to any one of <2> to <5>, wherein the first cover layer covers the external principal surface of the resin layer and a side surface of the resin layer continuous with the external principal surface.

<8> The stretchable device according to <7>, wherein the first cover layer is in contact with the first principal surface of the stretchable substrate.

<9> The stretchable device according to any one of <2> to <8>, wherein a dimension of the resin layer is equal to or more than a dimension of the first principal surface in a width direction of the stretchable wiring.

<10> The stretchable device according to any one of <1> to <9>, wherein a dimension of the first cover layer is larger than a dimension of the stretchable substrate in a width direction of the stretchable wiring.

<11> The stretchable device according to <10>, wherein the first cover layer covers the first principal surface of the stretchable substrate and a side surface of the stretchable substrate continuous with the first principal surface.

<12> The stretchable device according to any one of <1> to <11>, wherein a thickness of the first cover layer is 40 μm or more.

<13> The stretchable device according to any one of <2> to <12>, wherein a thickness of a region of the resin layer overlapping the stretchable wiring is smaller than a thickness of a region of the resin layer not overlapping the stretchable wiring.

<14> The stretchable device according to any one of <1> to <13>, wherein a surface of the first cover layer closest to the stretchable substrate has adhesiveness.

<15> The stretchable device according to any one of <1> to <14>, further including a second cover layer covering the second principal surface of the stretchable substrate.

<16> The stretchable device according to <15>, wherein the first cover layer and the second cover layer are in contact with each other in a region not overlapping the stretchable substrate.

<17> The stretchable device according to <15> or <16>, wherein a surface of the second cover layer closest to the stretchable substrate has adhesiveness.

<18> The stretchable device according to <17>, wherein a surface of the first cover layer closest to the stretchable substrate has bonding adhesiveness, and the surface having bonding adhesiveness of the first cover layer closest to the stretchable substrate and the surface having bonding adhesiveness of the second cover layer closest to the stretchable substrate are in contact with each other in a region not overlapping the stretchable substrate.

<19> The stretchable device according to <18>, wherein a plurality of contact portions exist between the first cover layer and the second cover layer, and the stretchable substrate is disposed between the plurality of contact portions in the width direction of the stretchable wiring.

<20> The stretchable device according to any one of <2> to <19>, wherein a plurality of the stretchable wirings facing away from each other are on the first principal surface of the stretchable substrate, and the resin layer is between adjacent stretchable wirings of the plurality of stretchable wirings.

The stretchable device of the present disclosure can be used by being worn on a human body.

### DESCRIPTION OF REFERENCE SYMBOLS

1: Stretchable substrate
2: Stretchable wiring
3: Resin layer
4: First cover layer
5: Second cover layer
6: First bonding adhesive layer
7: Second bonding adhesive layer
8: Contact portion
9: Void
10: External principal surface
11: First principal surface
12: Second principal surface
100, 101, 102, 103, 104, 105, 106, 107: Stretchable device

1. A stretchable device comprising:
a stretchable substrate having a first principal surface and a second principal surface;
a stretchable wiring on the first principal surface and containing a resin; and
a first cover layer covering at least a part of the stretchable wiring,
wherein a total organic carbon concentration in an extraction liquid when the stretchable device is immersed in ultrapure water for 24 hours is 15 mg/L or less.

2. The stretchable device according to claim 1, further comprising a resin layer in contact with at least a part of the stretchable wiring.

3. The stretchable device according to claim 2, wherein the first cover layer further covers at least a part of an external principal surface of the resin layer.

4. The stretchable device according to claim 1, wherein the total organic carbon concentration in an extraction liquid when the first cover layer is immersed in ultrapure water for 24 hours is 10 mg/L or less.

5. The stretchable device according to claim 1, wherein an elastic modulus of the first cover layer is smaller than an elastic modulus of the stretchable substrate.

6. The stretchable device according to claim 2, wherein a dimension of the first cover layer is larger than a dimension of the resin layer in a width direction of the stretchable wiring.

7. The stretchable device according to claim 2, wherein the first cover layer covers the external principal surface of the resin layer and a side surface of the resin layer continuous with the external principal surface.

8. The stretchable device according to claim 7, wherein the first cover layer is in contact with the first principal surface of the stretchable substrate.

9. The stretchable device according to claim 1, wherein a dimension of the resin layer is equal to or more than a dimension of the first principal surface in a width direction of the stretchable wiring.

10. The stretchable device according to claim 1, wherein a dimension of the first cover layer is larger than a dimension of the stretchable substrate in a width direction of the stretchable wiring.

11. The stretchable device according to claim 10, wherein the first cover layer covers the first principal surface of the stretchable substrate and a side surface of the stretchable substrate continuous with the first principal surface.

12. The stretchable device according to claim 1, wherein a thickness of the first cover layer is 40 μm or more.

13. The stretchable device according to claim 2, wherein a thickness of a region of the resin layer overlapping the stretchable wiring is smaller than a thickness of a region of the resin layer not overlapping the stretchable wiring.

14. The stretchable device according to claim 1, wherein a surface of the first cover layer closest to the stretchable substrate has adhesiveness.

15. The stretchable device according to claim 1, further comprising a second cover layer covering the second principal surface of the stretchable substrate.

16. The stretchable device according to claim 15, wherein the first cover layer and the second cover layer are in contact with each other in a region not overlapping the stretchable substrate.

17. The stretchable device according to claim 15, wherein a surface of the second cover layer closest to the stretchable substrate has adhesiveness.

18. The stretchable device according to claim 17, wherein
a surface of the first cover layer closest to the stretchable substrate has bonding adhesiveness, and
the surface having bonding adhesiveness of the first cover layer closest to the stretchable substrate and the surface having bonding adhesiveness of the second cover layer closest to the stretchable substrate are in contact with each other in a region not overlapping the stretchable substrate.

19. The stretchable device according to claim 18, wherein
a plurality of contact portions exist between the first cover layer and the second cover layer, and
the stretchable substrate is between the plurality of contact portions in the width direction of the stretchable wiring.

20. The stretchable device according to claim 2, wherein a plurality of the stretchable wirings facing away from each other are on the first principal surface of the stretchable substrate, and the resin layer is between adjacent stretchable wirings of the plurality of stretchable wirings.
